(19) United States
(12) Patent Application Publication
(10) Pub. No.: US 2003/0219961 A1
(43) Pub. Date: Nov. 27, 2003

(54) Method to reduce reflectivity of polysilicon layer

(76) Inventor: Shyh-Dar Lee, Hsinchu Hsien (TW)

Correspondence Address: NEEDLE & ROSENBERG, P.C., SUITE 1000, 999 PEACHTREE STREET, ATLANTA, GA, 30309-3915, US

(21) Appl. No.: 10/155,556

(22) Filed: May 24, 2002

(51) Int. Cl. C30B 1/00; H01L 21/20; H01L 21/469

(52) U.S. Cl. 438/478; 438/488; 438/787

(57) ABSTRACT

A method to reduce reflectivity of polysilicon layer. First, a semiconductor substrate is provided. The semiconductor substrate is placed in a single-wafer CVD chamber. Then, a silane-containing gas is introduced into the single-wafer CVD chamber to form a polysilicon layer on the semiconductor substrate. Next, hydrogen gas is introduced into the single-wafer CVD chamber to adjust the grain size of the upper surface of the polysilicon layer. Then, oxygen gas is introduced into the single-wafer CVD chamber to form a silicon oxide film on the polysilicon layer.

### BACKGROUND OF THE INVENTION

1. Field of the Invention

The present invention relates to the manufacture of semiconductor devices, more particularly, to a method for reducing reflectivity of a polysilicon layer by a single-wafer CVD chamber (in-situ process).

2. Description of the Related Art

During the manufacture of a semiconductor device, light from the photolithography system is passed through a photomask and the pattern transferred to the underlying photoresist layer. However, when the substrate underlying the photoresist layer is highly reflective, such as metal and polysilicon layers, light reflection can greatly destroy the pattern resolution by several mechanisms.

To eliminate light reflection, an anti-reflective layer (ARL) between a polysilicon layer and a photoresist layer, typically called bottom ARC has been widely used.

FIG. 1 shows a flowchart illustrating formation of polysilicon layer having low reflection surface according to the prior art. First, a semiconductor substrate is provided and placed in a batch-type chemical vapor deposition (CVD) chamber (S301). Then, Silane (SiH₄) is introduced into the batch-type chamber to form a polysilicon layer (S302). Next, the semiconductor substrate is transferred to a plasma enhanced chemical vapor deposition (PECVD) chamber (S303) followed by deposition of a silicon oxynitride layer as the antireflection layer (S304). Afterward, the polysilicon layer is patterned by conventional photolithography and etching (S305) to obtain desirable patterns, such as gate electrodes.

However, the batch-type CVD chamber has generally been employed in the formation of polysilicon layer to allow simultaneous processing of multiple wafers, thus presenting low processing times and low costs per wafer. Recent advances in circuit density miniaturization, however, have lowered tolerances for imperfections in semiconductor processing. For example, the polysilicon layers deposited by batch-type CVD chamber tend to disuniformity. Also, large quantities of particles and residue during deposition of the polysilicon layer in the batch-type chamber with relatively large volume can be a serious problem in the subsequent step.

Furthermore, polysilicon and anti-reflection layers such as silicon oxynitride are deposited in separate CVD tools. This can result in longer processing time. Therefore, improved methods to reduce reflectivity of polysilicon layer are needed.

### SUMMARY OF THE INVENTION

In view of the above disadvantages, an object of the invention is to provide a method to reduce reflectivity of polysilicon layer by a single-wafer CVD tool.

A further object of the invention is to provide a method to reduce reflectivity of polysilicon layer which can improve uniformity of deposited structures. Also, the polysilicon layer can be treated or reacted thus reducing the reflectivity in the same single-wafer chamber. Therefore, shorter processing time can be realized.

In accordance with one aspect of the invention, there is provided a method to reduce reflectivity of polysilicon layer. The semiconductor substrate is placed in a single-wafer CVD chamber. Then, a silane (SiH₄)-containing gas is introduced into the single-wafer CVD chamber to form a polysilicon layer on the semiconductor substrate. Next, hydrogen gas (H₂) is introduced into the single-wafer CVD chamber to adjust the grain size and structure of the upper surface of the polysilicon layer. Then, oxygen gas (O₂) is introduced into the single-wafer CVD chamber to form a silicon oxide film on the polysilicon layer.

In accordance with another aspect of the invention, there is provided a method to reduce reflectivity of polysilicon layer. The method further comprises a step of introducing ammonia gas (NH₃) and/or dinitrogen monoxide gas (N₂O) into the single-wafer CVD chamber for treatment of polysilicon layer to form a a silicon nitride film or a silicon oxynitride film.

In accordance with further aspect of the invention, there is provided a method to reduce reflectivity of polysilicon layer. The polysilicon layer preferably has a thickness of about 500 angstroms to 2500 angstroms. Also, the polysilicon layer is preferably deposited at a temperature of about 350° C. to 680° C., at a pressure of 150 mtorr to 400 mtorr. More preferably, the deposition temperature is between 350° C. and 550° C.

In accordance with yet another aspect of the invention, there is provided a method to reduce reflectivity of polysilicon layer. The method further comprises the steps of: transferring the semiconductor substrate to a PECVD chamber; and depositing a silicon oxynitride layer on the silicon oxide film.

In accordance with a still further aspect of the invention, there is provided a method to reduce reflectivity of polysilicon layer. First, a semiconductor substrate is provided. Then, the semiconductor substrate is placed in a single-wafer CVD chamber. Next, a silane-containing gas is introduced into the single-wafer CVD chamber to form a polysilicon layer on the semiconductor substrate. Then, ammonia gas and/or dinitrogen monoxide gas is introduced into the single-wafer CVD chamber to form a silicon oxynitride film on the polysilicon.

### BRIEF DESCRIPTION OF THE DRAWINGS

The preferred embodiment of the invention is hereinafter described with reference to the accompanying drawings in which:

FIG. 1 is a flowchart illustrating formation of polysilicon layer having low reflection surface according to the prior art.

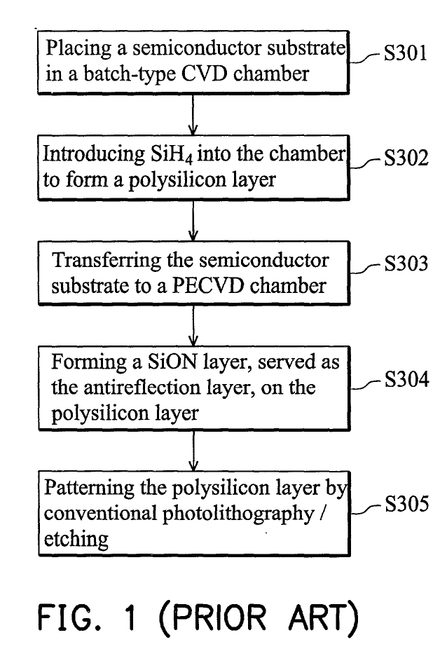

FIG. 2 is a flowchart illustrating formation of polysilicon layer having low reflection surface according to the first embodiment of the invention.

FIG. 3 is a flowchart illustrating formation of polysilicon layer having low reflection surface according to the second embodiment of the invention.

FIGS. 4A to 4D, are cross-sections showing the manufacturing steps to reduce reflectivity of polysilicon layer in accordance with the first embodiment of the invention.

FIGS. 5A to 5D, are cross-sections showing the manufacturing steps to reduce reflectivity of polysilicon layer in accordance with the second embodiment of the invention.

### DETAILED DESCRIPTION OF THE INVENTION

[First Embodiment]

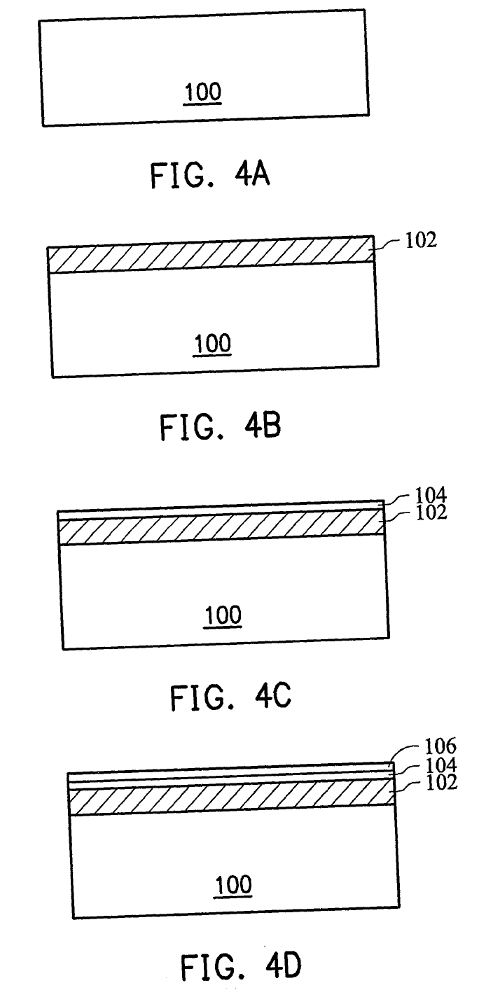

FIGS. 4A to 4D, are cross-sections showing the manufacturing steps to reduce reflectivity of polysilicon layer in accordance with the first embodiment of the invention.

Turning now to FIG. 4A, A semiconductor substrate (wafer) 100, made of single-crystalline silicon, is provided and placed in a single-wafer CVD chamber. For example TPCC (Thermal Process Common Centura), a single-wafer process tool, manufactured by Applied Materials (AMAT) is used.

As shown in FIG. 4B, a polysilicon layer 102 with a thickness of 500 to 2500 angstroms is deposited on the semiconductor substrate 100 by introducing a SiH₄ containing gas into the single-wafer CVD chamber. The polysilicon layer 102 is deposited at a temperature of about 350° C. to 680° C., at a pressure of about 150 mtorr to 400 mtorr.

Next, as shown in FIG. 4C, H₂ is introduced into the single-wafer CVD chamber mentioned above to adjust grain size and structure of the upper surface of the polysilicon layer 102. O₂ is then introduced into the single-wafer CVD chamber to form a silicon oxide film 104 on the polysilicon layer 102, thus reducing reflectivity of the polysilicon layer 102.

As shown in FIG. 4D, to further reduce reflectivity of the polysilicon layer 102, NH₃ and/or N₂O are preferably introduced into the single-wafer CVD chamber so that a thin film 106 consisting of silicon nitride or silicon oxynitride is grown on the polysilicon layer 102 having silicon oxide 104 thereon.

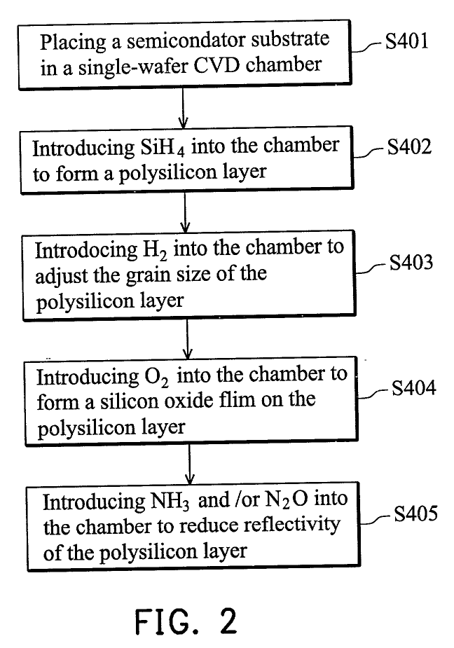

FIG. 2 is a flowchart illustrating formation of polysilicon layer having low reflection surface according to the first embodiment of the invention. This embodiment of the invention comprises steps S401 to 405. First, in S401, a semiconductor substrate is placed in a single-wafer CVD chamber. Then, in S402, SiH₄ is introduced into the chamber to form a polysilicon layer. Then, in S403, H₂ is introduced into the chamber to adjust the grain size of the polysilicon layer. Next, in S404, O₂ is introduced into the chamber to form a silicon oxide film on the polysilicon layer. Finally, in S405, NH₃ and/or N₂O are introduced into the chamber to reduce reflectivity of the polysilicon layer.

[Second Embodiment]

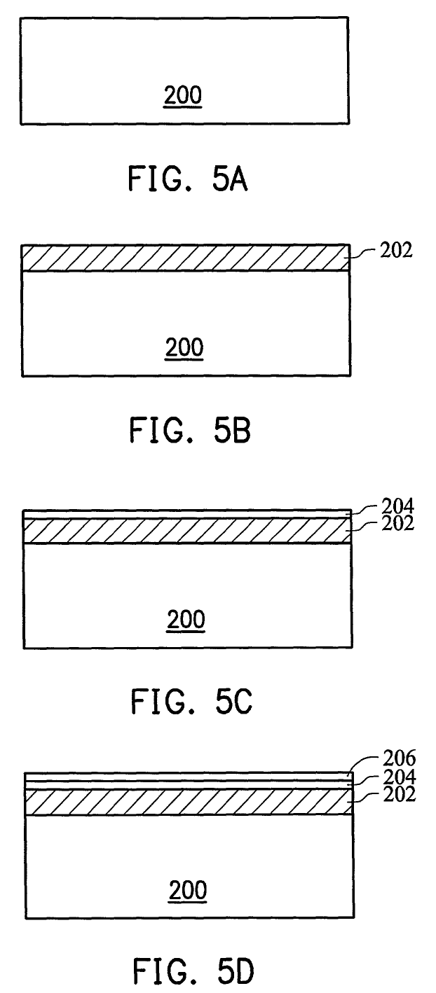

FIGS. 5A to 5D, are cross-sections showing the manufacturing steps to reduce reflectivity of polysilicon layer in accordance with the second embodiment of the invention.

Turning now to FIG. 5A, a semiconductor substrate (wafer) 200, made of single-crystalline silicon, is provided and placed in a single-wafer CVD chamber. For example TPCC (Thermal Process Common Centura), a single-wafer process tool, manufactured by Applied Materials (AMAT) is used.

As shown in FIG. 5B, a polysilicon layer 202 with a thickness of 500 angstroms to 2500 angstroms is deposited on the semiconductor substrate 200 by introducing a SiH₄ containing gas into the single-wafer CVD chamber. The polysilicon layer 202 is deposited at a temperature of about 350° C. to 680° C., at a pressure of about 150 mtorr to 400 mtorr.

Next, as shown in FIG. 5C, NH₃ and/or N₂O are introduced into the single-wafer CVD chamber so that a thin film 204 consisting of silicon nitride or silicon oxynitride is grown on the polysilicon layer 202. The thin film 204, capable of reducing reflectivity of the polysilicon layer 204, is deposited in the same chamber used for deposition of the polysilicon layer 204.

Referring to FIG. 5D, the semiconductor substrate 200 is then transferred to a plasma enhanced chemical vapor deposition (PECVD) chamber. Next, a silicon oxynitride layer 206, serving as the anti-reflection layer, is formed on the thin film 204 to further reduce reflectivity of the polysilicon layer 202.

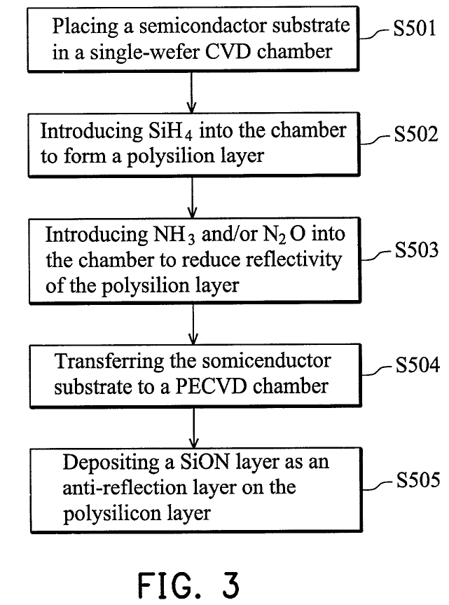

FIG. 3, is a flowchart illustrating formation of polysilicon layer having low reflection surface according to the second embodiment of the invention. This embodiment of the invention comprises the steps of S501 to S505. First, in S501, a semiconductor substrate is placed in a single-wafer CVD chamber. Then, in S502, SiH₄ is introduced into the chamber to form a polysilicon layer. Then, in S503, NH₃ and/or N₂O are introduced into the chamber to reduce reflectivity of the polysilicon layer. Next, in S504, the semiconductor substrate is transferred to a PECVD chamber. Finally, in S505, a silicon oxynitride (SiON) layer is deposited as the anti-reflection layer on the polysilicon layer.

According to the method of the invention, the deposited polysilicon layer uniformity can be improved. Also, the polysilicon layer can be treated or reacted thus reducing the reflectivity in the same single-wafer chamber. Therefore, shorter processing time can be realized.

While the invention has been described with reference to various illustrative embodiments, the description is not intended to be construed in a limiting sense. Various modifications of the illustrative embodiments, as well as other embodiments of the invention, will be apparent to those person skilled in the art upon reference to this description. It is therefore contemplated that the appended claims will cover any such modifications or embodiments as may fall within the scope of the invention defined by the following claims and their equivalents.

What is claimed is:

1. A method to reduce reflectivity of polysilicon layer, comprising the steps of:
providing a semiconductor substrate;
placing the semiconductor substrate in a single-wafer CVD chamber;
introducing a silane-containing gas into the single-wafer CVD chamber to form a polysilicon layer on the semiconductor substrate;
introducing hydrogen gas into the single-wafer CVD chamber to adjust the grain size of the upper surface of the polysilicon layer; and
introducing oxygen gas into the single-wafer CVD chamber to form a silicon oxide film on the polysilicon layer.

2. A method to reduce reflectivity of polysilicon layer as claimed in claim 1, further comprising the step of introducing ammonia gas into the single-wafer CVD chamber for treatment of the polysilicon layer to form a silicon nitride film.

3. A method to reduce reflectivity of polysilicon layer as claimed in claim 1, further comprising the step of introducing dinitrogen monoxide gas into the single-wafer CVD chamber for treatment of the polysilicon layer to form a silicon oxynitride film.

4. A method to reduce reflectivity of polysilicon layer as claimed in claim 1, wherein the polysilicon layer has a thickness of about 500 angstroms to 2500 angstroms.

5. A method to reduce reflectivity of polysilicon layer as claimed in claim 1, wherein the polysilicon layer is deposited at a temperature of about 350° C. to 680° C.

6. A method to reduce reflectivity of polysilicon layer as claimed in claim 1, wherein the polysilicon layer is deposited at a pressure of 150 mtorr to 400 mtorr.

7. A method to reduce reflectivity of polysilicon layer as claimed in claim 1, further comprising the steps of:
transferring the semiconductor substrate to a PECVD chamber; and
depositing a silicon oxynitride layer on the silicon oxide film.

8. A method to reduce reflectivity of polysilicon layer, comprising the steps of:
providing a semiconductor substrate;
placing the semiconductor substrate in a single-wafer CVD chamber;
introducing a silane-containing gas into the single-wafer CVD chamber to form a polysilicon layer on the semiconductor substrate;
introducing ammonia gas and dinitrogen monoxide gas into the single-wafer CVD chamber to form a silicon oxynitride film on the polysilicon.

9. A method to reduce reflectivity of polysilicon layer as claimed in claim 8, wherein the polysilicon layer has a thickness of about 500 angstroms to 2500 angstroms.

10. A method to reduce reflectivity of polysilicon layer as claimed in claim 8, wherein the polysilicon layer is deposited at a temperature of about 350° C. to 680° C.

11. A method to reduce reflectivity of polysilicon layer as claimed in claim 8, wherein the polysilicon layer is deposited at a pressure of 150 mtorr to 400 mtorr.

12. A method to reduce reflectivity of polysilicon layer as claimed in claim 8, further comprising the steps of:
transferring the semiconductor substrate to a PECVD chamber; and
depositing a silicon oxynitride layer on the polysilicon layer.
